(19) United States
(12) Patent Application Publication
(10) Pub. No.: US 2009/0201714 A1
(43) Pub. Date: Aug. 13, 2009

(54) RESISTIVE MEMORY CELL AND METHOD FOR OPERATING SAME

(76) Inventor: Heinz Hoenigschmid, Poecking (DE)

Correspondence Address: PATTERSON & SHERIDAN, LLP;Gero McClellan / Qimonda, 3040 POST OAK BLVD.,, SUITE 1500, HOUSTON, TX, 77056, US

(21) Appl. No.: 12/028,711

(22) Filed: Feb. 8, 2008

(51) Int. Cl. G11C 11/00

(52) U.S. Cl. 365/148

(57) ABSTRACT

An integrated circuit comprising at least one resistive memory cell, comprising a resistive memory element and a selection device, said resistive memory element having at least two resistive OFF-states, each OFF-state defining a predefined resistance value is described. Moreover, a memory, a computing system and method of operating a memory are described.

### BACKGROUND OF THE INVENTION

Resistive memories make use of a memory element that can change its electrical resistance through suitable programming. Accordingly, the memory element comprises a resistive storage medium that exhibits at least two different states having different electrical resistance. One of theses states may be a high resistive state and the other may be a low resistive state. The resistive storage medium may be switched between theses states through suitable programming.

In conductive bridge RAM (CBRAM) memory cells, also referred to as programmable metallization cells (PMC) as well as phase change RAM (PCRAM) memory cells, the logical information may be stored by changing the resistance of the cell. During reading of the information stored in the cell, the resistance will not be altered as long as a predetermined voltage condition can be maintained. For evaluating the content of a memory cell it is necessary to evaluate the resistance value of the cells or the current flowing through the cell, respectively.

Details of one or more implementations are set forth in the accompanying exemplary drawings and exemplary description below. Other features will be apparent from the description and drawings, and from the claims.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 shows a schematic view of an integrated circuit according to an embodiment.

FIG. 2 shows a schematic view of an integrated circuit according to another embodiment.

FIG. 3 shows a schematic view of resistance value for a data cell and reference cells according to an embodiment.

FIG. 4 shows a schematic view of a computing system according to an embodiment.

FIG. 5 shows a schematic flow diagram of a method of operating a memory according to an embodiment.

### DETAILED DESCRIPTION OF THE PREFERRED EMBODIMENT

This description is directed generally to an integrated circuit comprising a resistive memory cell, a memory, a computing system and a method of operating a memory.

According to one embodiment, an integrated circuit may comprise at least one resistive memory cell comprising a resistive memory element and a selection device, said resistive memory element having at least two resistive OFF-states, each OFF-state defining a predefined resistance value.

The integrated circuit may further comprise at least one resistive reference cell, comprising a resistive reference element and a selection device, said resistive reference element defining a reference resistance value for distinguishing the predefined resistance values of said resistive memory cell.

Said resistive reference cell may be a resistive memory cell which in use takes a predefined state or reference resistance value. Said resistive reference value may be a predefined value.

PCRAM memory cells may comprise a resistive memory element comprising a phase change material being located between two electrodes. The phase change material may be a metal alloy. For example, by the use of electrical pulses, the phase change material can be heated and switched between an amorphous and a crystalline phase state. These phase states may be used for storing information. The switching to the crystalline state may be referred to as programming or setting the resistive memory cell. In the crystalline state, the memory cell is in at least one ON-state. The switching to the amorphous state may be referred to as deleting, un-programming or resetting the resistive memory cell. In the amorphous state, the memory cell is in at least one OFF-state.

The programming of the resistive memory element may be done by applying a current of a predetermined intensity, e.g. ten to few hundred μA, for a predetermined time, e.g. 100 ns, and ramping down the current to 0 A rather slowly, e.g. within 300 ns. The deleting of the resistive memory element may be done by applying a current of a predetermined intensity, e.g. several hundred μA, for a predetermined time, e.g. 50 ns, and ramping down the current to 0 A rather fast, e.g. within 5 ns. Thus, the programming is performed by applying a rather low current for a longer time, whereas the deleting is performed by applying a higher current for a shorter time. Thus, depending on the slope of the of current-over-time curve, the programming and un-programming, and thus ON and OFF states of a resistive memory cell can be distinguished.

CBRAM memory cells comprise a resistive memory element comprising an electrolyte material being located between two electrodes. The electrolyte material may have a high specific resistance. By applying a programming voltage to the electrodes, a conductive path in the electrolyte material may be formed. This conductive path can again be destroyed by applying a respective delete voltage. Said delete voltage may be a voltage of inverse polarity compared with the programming voltage. The presence or absence of the conductive path may be used for storing information. The establishment of said conductive path may be referred to as programming or setting the resistive memory cell. When a conductive path is established or in the process of being established, the memory cell is in an ON-state. The absence or destroying of said conductive path may be referred to as deleting, un-programming or resetting the resistive memory cell. When a conductive path is basically not present or in the process of being destroyed, the memory cell is in an OFF-state.

It is to be noted that for both PCRAM and CBRAM, the resistance value of the resistive memory element is changed when switching from the ON-state to the OFF-state. Moreover, in the ON-state and/or OFF-state, the resistive memory element may take one of a plurality of resistance values. For example, the resistive memory element may have at least two resistive OFF-states. In addition, said resistive memory element may have at least one resistive ON-state.

In order to distinguish the different states of said resistive memory element, one or more reference cells or reference memory cells may be used. Each of said reference cells may have a predefined reference resistance value assigned thereto. The reference resistance value may be chosen such to respectively lie between two resistance values a resistive memory element may take. In order to distinguish n different states of a resistive memory element, n−1 reference cells may be used.

In one embodiment, said reference resistance value(s) may be provided in a resistive OFF-state of said resistive reference element.

In another embodiment, said reference resistance value(s) may be provided in a resistive ON-state of said resistive reference element.

In a further embodiment, at least two resistive reference cells may be provided and a first of said reference resistance values may be provided in a resistive OFF-state of one of said resistive reference cells, and a second of said reference resistance values being provided in a resistive ON-state of the other of said resistive reference cells.

FIG. 1 shows a schematic view of an integrated circuit 200 according to an embodiment.

Said integrated circuit 200 may comprise a plurality of resistive memory cells 210, of which one is exemplarily shown in FIG. 1. Resistive memory cell 210 comprises a resistive storage element 211 and a selection device 212, which may be a selection transistor. The resistance of the resistive memory element 211 indicates the memory state of the memory cell 210.

In one embodiment, resistive memory cells 210 may be CBRAM-memory cells in which the resistive memory element 211 comprises two electrodes and an electrolyte material being located between the electrodes, said electrolyte material having a high specific resistance. Resistive memory cell 210 is thus in a high resistive memory state or OFF state if the resistive memory element 211 is not programmed. By applying voltages to the electrodes a conductive path in the electrolyte material can be established or destroyed. Depending on the degree of establishing or destroying of the conductive path in the electrolyte material of the resistive memory element 211 the resistive memory cell 210 can take one of several memory states. In particular, the resistive memory element may have at least two resistive OFF states.

The resistive memory cell 210 shown in FIG. 1 can, in one embodiment, be programmed to have one of four possible memory states for storing two-bit information. The memory cell 210 may be switchable between three high resistance memory states and one low resistance memory state. In one embodiment, in the high resistance memory states or OFF states memory cell 210 may have an effective electric resistance of 1 GΩ, 200 kΩ and 100 kΩ, whereas the low resistance memory state or ON state may have a resistance value of 50 kΩ.

The evaluation of the memory state of resistive memory cell 210 can be performed by the use of three reference cells 220 being associated with memory cell 210. Said reference cells 220 have reference states with resistance values between the single memory states or resistance values of memory cell 210. In one embodiment, the reference states of reference cells 220 may be in a low resistive memory state or ON state of the reference cells 220. The resistance values may e.g. be 250 kΩ, 150 kΩ and 75 kΩ. In a further embodiment, the resistance values of the reference cells 220 may be provided in a high resistive memory state or OFF state of the reference cells or mixed, i.e. some in an OFF state and some in an ON state. As there is an overlap in the resistance values in the resistive ON and OFF states, it is possible to use resistance values in an ON state for evaluating a resistance value in an OFF state and vice versa.

Reference cells 220, as shown in FIG. 1, may be resistive memory cells with respectively a resistive memory element 211 and a selection device 212, which are switched to the respective different reference states. Both for memory cell 210 and reference cells 220 a first contact of the resistive memory element 211 may be connected with a power supply 12 and a second contact of the resistive memory element 211 is connected with a first source/drain contact of the selection transistor 212. Potential 12 can also be referred to as plate potential. A second source/drain contact of the selection transistor 212 may be connected with a bit line 21, and a gate of the selection transistor 212 may be connected with a word line 20.

For reference cells 220, the respective bit line may be connected with a first source/drain contact of a transistor 50. A gate of transistor 50 may be connected with a control line 25, and a second source/drain contact of transistor 50 may be connected with a first contact of a transistor being used as a diode 30. Ground potential 10 may be applied to the second contact of diode 30. A voltage drop at the diode may be sampled or scanned by one of three read amplifiers 40. Amplifiers 40 may thus be connected by corresponding lines with a contact of one diode 30 or respective node 31-1, 31-2 or 31-3, respectively between the diode 30 and transistor 50, for picking off a potential being present at respective node 31-1, 31-2 or 31-3.

In contrast to this for memory cells 210, instead of transistor 50, a voltage control unit 60 may be provided. Voltage control unit 60 may comprise an operational amplifier 61 and a control transistor 62. The source/drain contacts of the control transistor 62 may be connected with bit line 21 and a diode 30, respectively, and the gate of control transistor 62 may be connected with the output of operational amplifier 61. A constant reference potential 11 may be applied to a first input of the operational amplifier 61. A potential being present on node 64 or the source/drain contact of the control transistor 62 may be fed back to a second input of the operational amplifier 61.

For scanning a voltage drop at diode 30, the three read amplifiers 40 may be connected by corresponding lines with respective contacts of diode 30 (nodes 31-1, 30-2, 30-3, respectively) between diode 30 and control transistor 62. Ground potential 10 may be applied to a second contact of diode 30.

For evaluating the memory state of memory cell 210, word line 20 may be activated by applying a respective activating potential. Selection transistors 212 of memory cells 210 and the reference cells 220 are switched through. Thus, the resistive memory elements 211 of memory cell 210 and reference cells 220 may be connected by the switched selection transistors 212 with bit lines 21.

Moreover, a respective predefined read voltage 15, 15-1, 15-2, 15-3 may be applied to memory cell 210 as well as reference cells 220 to cause an electric current in the respective lines from power supply 12 to ground potential 10, the value of said current depending on the resistance states in memory cell 210 and reference cells 220. The read voltage 15, 15-1, 15-2, 15-3 drops at the resistive memory elements 211.

The electric current in the respective bit lines 21 is transferred into a voltage drop at diodes 30 associated with memory cell 210 and reference cells 220, and thus the potentials at the contacts of diodes 30 or respective node 31-1, 31-2 or 31-3, are scanned by read amplifiers 40. Thus, respectively one of the potentials of respective node 31-1, 31-2, 31-3 of reference cells 220 is picked off by one of the three read amplifiers 40 and the potential of respective node 31-1, 31-2, 31-3 associated with memory cells 210 is picked off by all three read amplifiers 40 for comparing the potentials. The respective differences of the picked off potentials from respective node 31-1, 31-2, 31-3 are amplified by read amplifiers 40. By the use of the amplified potential differences the memory state of memory cell 210 can be determined.

FIG. 2 shows a schematic view of an integrated circuit according to another embodiment. The structure of integrated circuit 300 and the functioning thereof basically corresponds to the one shown in FIG. 1.

Resistive memory cell 310 comprising a resistive memory element 311 and a selection transistor 312 may be a PCRAM memory cell. In this embodiment, the resistive memory element 311 may comprise two electrodes and a phase change material located between the electrodes. By applying electric pulses to the electrodes, the phase change material can be heated and switched between an amorphous and a crystalline phase state. Depending on the degree of the amorphous and crystalline state, several high resistance and low resistance states can be distinguished.

The memory state of memory cell 310 can be determined by the use of three reference cells 320.

The basic differences to the circuit 200 shown in FIG. 1 are that potentials 10 and 12 are exchanged and the resistive memory elements 311 and selection transistors 312 in memory cell 310 and reference cells 320 are also exchanged. Diodes 30 are connected with a power supply 12 and memory cell 310 and reference cells 320 are connected with ground potential 10. Moreover, the resistive memory element 311 of memory cell 310 and reference cells 320 is directly contacted with bit line 21 whereas, a selection transistor 312 which can be activated by a word line 20 is connected with ground potential 10.

The method of evaluating the resistance value of resistive memory cell 310 is analogous to the one described in connection with FIG. 1.

The integrated circuits shown in FIGS. 1 and 2 may be used as a memory.

FIG. 3 shows a schematic view of resistance value for a data cell and reference cells according to an embodiment.

In FIG. 3, four resistive states being represented by four different resistance values of one resistive memory cell being used as a data cell are shown. The resistance values correspond to those used in the examples discussed with respect to FIGS. 1 and 2. In these embodiments, the data cell can take three resistive OFF states and one resistive ON state. The resistive OFF states representing the two bit-data of “11”, “10” and “01”, said states being represented by resistance values 1 GΩ, 200 kΩ and 100 kΩ, respectively. The resistive ON state represents the two bit-data of “00”, said state being represented by resistance value 50 kΩ.

The reference cells may take a predefined resistance value which lies between the resistance values the data cell can take. In the present embodiment, the reference cells have resistance values 250 kΩ, 150 kΩ and 75 kΩ, said resistance values being provided in the ON state of the resistive memory cells.

It is to be noted that the resistance value in the resistive OFF state of a resistive memory cell may lie in the range of 100 kΩ to several GQ. The resistance value in the resistive ON state of a resistive memory cell may lie in the range of 10 kΩ to 300 kΩ. Therefore, there is an overlap in the resistance values in the resistive ON and OFF states. Thus, it is possible to use resistance values in an ON state for evaluating a resistance value in an OFF state and vice versa.

According to a further embodiment, a computing system may comprise an input apparatus, an output apparatus, a processing apparatus, and a memory. Said memory may comprise a data bit array of resistive memory cells, said resistive memory cells may each comprise a resistive memory element and a selection device, said resistive memory element may have at least two resistive OFF-states, each OFF-state defining a predefined resistance value.

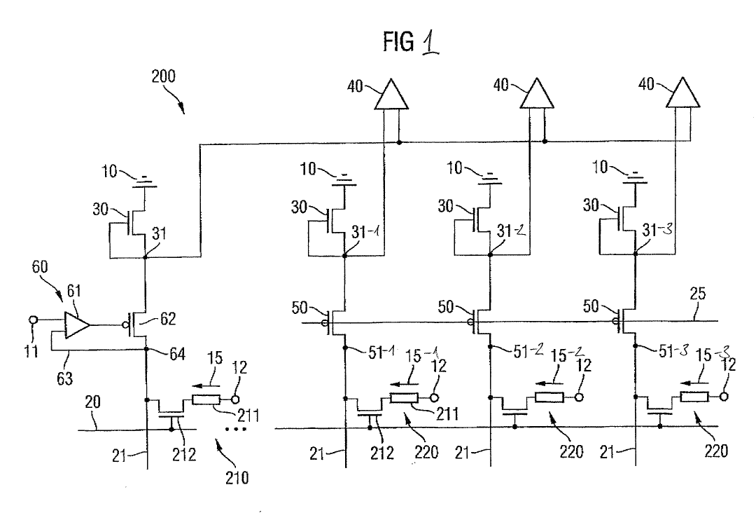

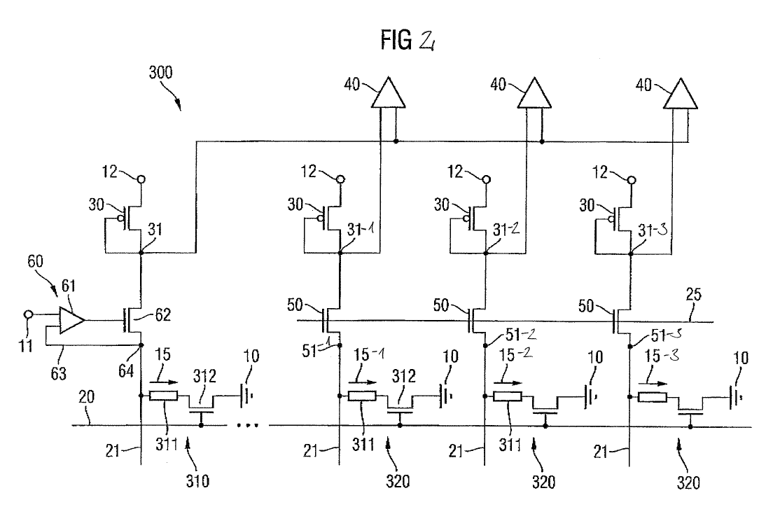

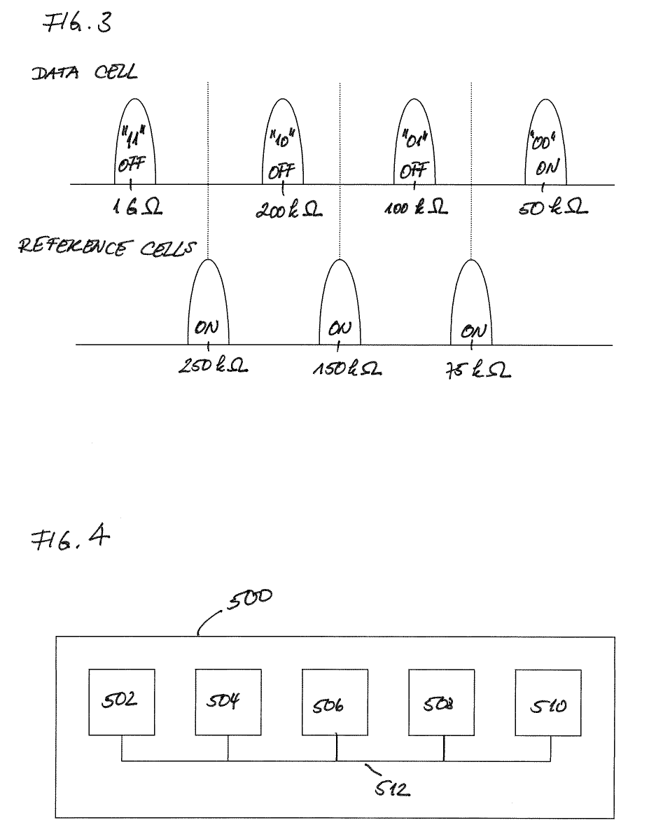

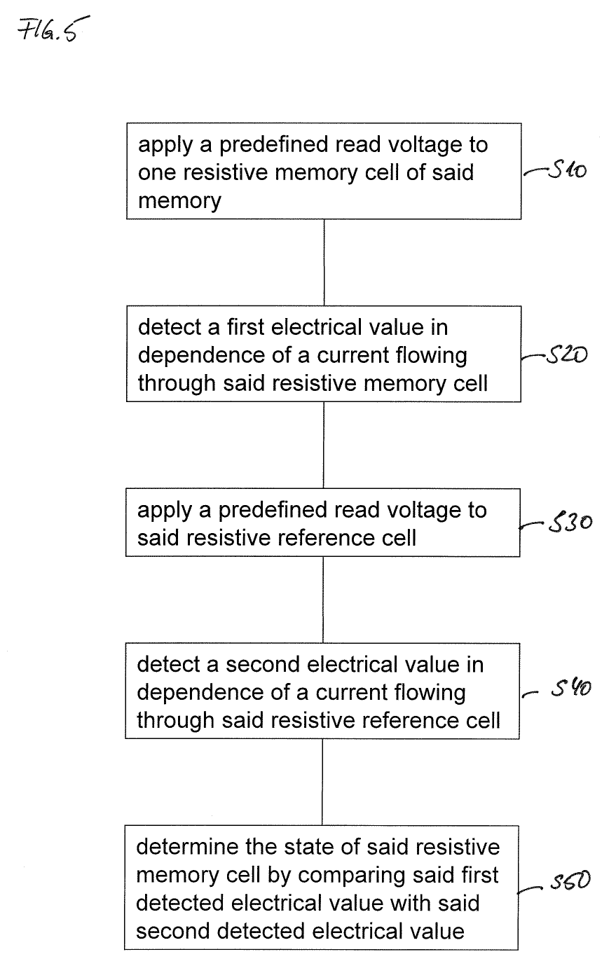

In accordance yet a further embodiment, memory devices that include memory cells or memory elements as described herein may be used in a variety of applications or systems, such as the illustrative computing system shown in FIG. 4. The computing system 500 may include a memory device 502, which may include integrated circuits as described herein above. The system may also include a processing apparatus 504, such as a microprocessor or other processing device or controller, as well as input and output apparatus, such as a keypad 506, display 508, and/or wireless communication apparatus 510. The memory device 502, processing apparatus 504, keypad 506, display 508 and wireless communication apparatus 510 are interconnected by a bus 512.

The wireless communication apparatus 510 may have the ability to send and/or receive transmissions over a cellular telephone network, a WiFi wireless network, or other wireless communication network. It will be understood that the various input/output devices shown in FIG. 4 are merely embodiments. Memory devices including integrated circuits of the above-mentioned embodiments may be used in a variety of systems. Alternative systems may include a variety of input and output devices, multiple processors or processing apparatus, alternative bus configurations, and many other configurations of a computing system. Such systems may be configured for general use, or for special purposes, such as cellular or wireless communication, photography, playing music or other digital media, or any other purpose now known or later conceived to which an electronic device or computing system including memory may be applied.

According to another embodiment, a memory may comprise a data bit array of resistive memory cells. Said resistive memory cells each may comprise a resistive memory element and a selection device. Said resistive memory element may have at least two resistive OFF-states, each OFF-state defining a predefined resistance value.

According to a further embodiment, a method of operating a memory may comprise the steps discussed in the following. Said memory may comprise a data bit array of resistive memory cells, said resistive memory cells may each comprise a resistive memory element and a selection device, said resistive memory element may have at least two resistive OFF-states, each OFF-state defining a predefined resistance value, and a reference bit array comprising at least one resistive reference cell. Said resistive reference cell may comprise a resistive reference element and a selection device. Said resistive reference element may define a reference resistance value for distinguishing the predefined resistance values of said resistive memory cells. Said method may comprise the steps of:
applying a predefined read voltage to one resistive memory cell of said memory;
detecting a first electrical value in dependence of a current flowing through said resistive memory cell, said current being caused by said read voltage;
applying a predefined read voltage to said resistive reference cell;
detecting a second electrical value in dependence of a current flowing through said resistive reference cell, said current being caused by said read voltage; and
determining the state of said resistive memory cell by comparing said first detected electrical value with said second detected electrical value.

FIG. 5 shows a schematic flow diagram of an embodiment of method of operating a memory. Said memory may be an integrated circuit as shown in FIG. 1 or 2.

The method may comprise a first step of applying a predefined read voltage to one resistive memory cell of said memory (step S10). Moreover, the method may comprise a step of detecting a first electrical value in dependence of a current flowing through said resistive memory cell, said current being caused by said read voltage (Step S20). Furthermore, a predefined read voltage may be applied to said resistive reference cell (Step S30) and a second electrical value in dependence of a current flowing through said resistive reference cell may be detected (Step S40). Said current may be caused by said read voltage. Finally the state of said resistive memory cell may be determined by comparing said first detected electrical value with said second detected electrical value (Step S50).

The method of operating a memory may furthermore be performed as described above in connection with FIG. 1 or 2.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

1. An integrated circuit, comprising:
at least one resistive memory cell comprising a resistive memory element and a selection device, said resistive memory element having at least two resistive OFF-states, each OFF-state defining a predefined resistance value.

2. The integrated circuit according to claim 1, further comprising at least one resistive reference cell, comprising a resistive reference element and a selection device, said resistive reference element defining a reference resistance value for distinguishing the predefined resistance values of said resistive memory cell.

3. The integrated circuit according to claim 2, wherein said reference resistance value is provided in a resistive OFF-state of said resistive reference element.

4. The integrated circuit according to claim 2, wherein said reference resistance value is provided in a resistive ON-state of said resistive reference element.

5. The integrated circuit according to claim 1, further comprising at least two resistive reference cells, each comprising a resistive reference element and a selection device, each of said resistive reference elements defining a reference resistance value, said reference resistance values being used for distinguishing the predefined resistance values of said resistive memory cell, a first of said reference resistance values being provided in a resistive OFF-state of one of said resistive reference elements, and a second of said reference resistance values being provided in a resistive ON-state of the other of said resistive reference elements.

6. The integrated circuit according to claim 1, wherein an OFF-state is defined when said resistive memory element is deleted.

7. The integrated circuit according to claim 1, wherein said resistive memory cell is a PCRAM memory cell and said OFF-state is defined by said resistive memory element being in the amorphous phase.

8. The integrated circuit according to claim 1, wherein said resistive memory cell is a CBRAM memory cell in which a conductive path is formed when said resistive memory element is programmed and said path is destroyed when said resistive memory element is deleted, and said OFF-state is defined by said conductive path being destroyed.

9. The integrated circuit according to claim 1, wherein said resistive memory element further has at least one resistive ON-state, said ON-state defining a predefined resistance value.

10. The integrated circuit according to claim 9, further comprising at least two resistive reference cells, each comprising a resistive reference element and a selection device, each of said resistive reference elements defining a reference resistance value, said reference resistance values being used for distinguishing the predefined resistance values of said resistive memory cell.

11. The integrated circuit according to claim 10, wherein said reference resistance values are provided in a resistive OFF-state of said resistive reference element.

12. The integrated circuit according to claim 10, wherein said reference resistance values are provided in a resistive ON-state of said resistive reference element.

13. The integrated circuit according to claim 9, wherein a first of said reference resistance values is provided in a resistive OFF-state of one of said resistive reference elements, and a second of said reference resistance values is provided in a resistive ON-state of the other of said resistive reference elements.

14. The integrated circuit according to claim 9, wherein an ON-state is defined when said resistive memory element is programmed.

15. The integrated circuit according to claim 9, wherein said resistive memory cell is a PCRAM memory cell and said ON-state is defined by said resistive memory element being in the crystalline phase.

16. The integrated circuit according to claim 9, wherein said resistive memory cell is a CBRAM memory cell in which a conductive path is formed when said resistive memory element is programmed and said path is destroyed when said resistive memory element is deleted, and said ON-state is defined by said conductive path being formed.

17. An integrated circuit, comprising:
at least one resistive memory cell comprising a resistive memory element and a selection device, said resistive memory element having at least two resistive OFF-states, each OFF-state defining a predefined resistance value; and
at least one resistive reference cell, comprising a resistive reference element and a selection device, said resistive reference element defining a reference resistance value, said reference resistance value lying between said predefined resistance values of said resistive memory cell.

18. An integrated circuit, comprising:
at least one resistive memory cell comprising a resistive memory element and a selection device, said resistive memory element having at least three resistive states, each state being defined by a predefined resistance value; and
at least two resistive reference cells, each comprising a resistive reference element and a selection device, each of said resistive reference elements defining a reference resistance value, said reference resistance values being used for distinguishing the predefined resistance values of said resistive memory cell.

19. A memory, comprising:
a data bit array of resistive memory cells, said resistive memory cells each comprising a resistive memory element and a selection device, said resistive memory element having at least two resistive OFF-states, each OFF-state defining a predefined resistance value.

20. The memory according to claim 19, further comprising
a reference bit array comprising at least one resistive reference cell, said resistive reference cell comprising a resistive reference element and a selection device, said resistive reference element defining a reference resistance value for distinguishing the predefined resistance values of said resistive memory cells.

21. A computing system, comprising:
an input apparatus;
an output apparatus;
a processing apparatus; and
a memory, said memory comprising a data bit array of resistive memory cells, said resistive memory cells each comprising a resistive memory element and a selection device, said resistive memory element having at least two resistive OFF-states, each OFF-state defining a predefined resistance value.

22. The computing system according to claim 21, wherein said memory further comprises:
a reference bit array comprising at least one resistive reference cell, said resistive reference cell comprising a resistive reference element and a selection device, said resistive reference element defining a reference resistance value for distinguishing the predefined resistance values of said resistive memory cells.

23. A method, comprising:
providing a memory, comprising:
a data bit array of resistive memory cells, wherein said resistive memory cells each comprise a resistive memory element and a selection device, wherein said resistive memory element has at least two resistive OFF-states, and wherein each OFF-state defines a predefined resistance value; and
a reference bit array, wherein the reference bit array comprises at least one resistive reference cell, wherein said resistive reference cell comprises a resistive reference element and a selection device, and wherein said resistive reference element defines a reference resistance value for distinguishing the predefined resistance values of said resistive memory cells;
applying a predefined read voltage to one resistive memory cell of said memory;
detecting a first electrical value in dependence of a current flowing through said resistive memory cell, said current being caused by said read voltage;
applying a predefined read voltage to said resistive reference cell;
detecting a second electrical value in dependence of a current flowing through said resistive reference cell, said current being caused by said read voltage; and
determining the state of said resistive memory cell by comparing said first detected electrical value with said second detected electrical value.
